(19) United States
(12) Patent Application Publication
(10) Pub. No.: US 2025/0006501 A1
(43) Pub. Date: Jan. 2, 2025

(54) PRE-WAFER FABRICATION LASER DICING

(71) Applicant: TEXAS INSTRUMENTS INCORPORATED, Dallas, TX (US)

(72) Inventors: Hao ZHANG, Chengdu (CN); Min Hui MA, Chengdu (CN); Qing RAN, Chengdu (CN); Guan Quan WEN, Chengdu (CN); Joseph O. LIU, Cary, NC (US); Yang LIU, Chengdu (CN)

(21) Appl. No.: 18/345,490

(22) Filed: Jun. 30, 2023

(51) Int. Cl. H01L 21/304; B23K 26/354; B23K 26/53; H01L 21/683

(52) U.S. Cl. CPC H01L 21/304; B23K 26/354; B23K 26/53; H01L 21/6836; B23K 2101/40; B23K 2103/56

(57) ABSTRACT

In examples, a method for manufacturing a semiconductor die comprises, prior to forming circuitry on a semiconductor wafer, forming a horizontal array of cracks in an interior of the wafer using a laser. The method also includes, after forming the horizontal array of cracks, forming circuitry on a device side of the wafer. The method includes forming conductive bumps on the device side of the wafer.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation.

### SUMMARY

In examples, a method for manufacturing a semiconductor die comprises, prior to forming circuitry on a semiconductor wafer, forming a horizontal array of cracks in an interior of the wafer using a laser. The method also includes, after forming the horizontal array of cracks, forming circuitry on a device side of the wafer. The method includes forming conductive bumps on the device side of the wafer.

In examples, a semiconductor device comprises a semiconductor die having a device side in which circuitry is formed and a non-device side opposite the device side, the device side having sustained laser damage, the circuitry free of laser damage. The device also comprises a mold compound covering the semiconductor die.

### BRIEF DESCRIPTION OF THE DRAWINGS

FIG. 1 is a flow diagram of a method for manufacturing a semiconductor device, in accordance with various examples.

FIGS. 2A-10C are a process flow for manufacturing a semiconductor device, in accordance with various examples.

### DETAILED DESCRIPTION

As described above, during wafer fabrication, multiple integrated circuits are formed in a single wafer. After wafer fabrication, the wafer is singulated into individual dies, with each die containing one of the integrated circuits formed during fabrication.

The singulation process is often performed using a laser (sometimes referred to as a laser saw). The laser is directed to an interior of the wafer where the wafer is intended to be cut. The laser energy applied to the interior of the wafer forms a vertical crack in the wafer. This crack does not extend through the entire thickness of the wafer, and so the various components of the wafer remain connected to each other. Many such cracks may be formed in the wafer, usually in the grid-like “saw streets” of the wafer that separate the fabricated integrated circuits from each other.

Typically, the vertical crack formed by a single pass of the laser is small. Thus, multiple passes of the laser are needed in a single location to form multiple vertical cracks in alignment with each other. For example, a first laser pass may be directed to a first location within the thickness of the wafer to form a first vertical crack, and then a second laser pass may be directed to a second location within the thickness of the wafer (e.g., a predetermined distance below the first location) to form a second vertical crack. The vertical cracks may join with each other, thus forming a continuous, large, vertical crack.

In some situations, when the laser is applied to the first location, the resulting first vertical crack extends farther vertically than intended. For example, the first vertical crack may extend deeper into the wafer than intended, even as far as the second location where the second laser pass is intended to be applied. If this happens, then when the second laser pass is applied at the second location, the laser light meets with some part of the first vertical crack. When the laser light meets the first vertical crack, it reflects off of the contours of the wafer along the first vertical crack, causing the laser light to scatter, or “splash.” This undesirable scatter of laser light often reaches the integrated circuits of the wafer and damages the circuits. Such damage significantly reduces manufacturing yield. This damage may be referred to as “splash damage.”

This disclosure describes various examples of a method for manufacturing a semiconductor device that avoids the integrated circuit laser damage described above. In particular, the method includes, prior to forming circuitry on a semiconductor wafer, forming a horizontal array of cracks in an interior of the wafer using a laser. The method also comprises, after forming the horizontal array of cracks, forming circuitry on a device side of the wafer. The method further includes forming conductive bumps on the device side of the wafer. The resulting semiconductor device includes a semiconductor die having a device side in which circuitry is formed and a non-device side opposite the device side. The device side has sustained laser damage, and the circuitry is free of laser damage. The device also includes a mold compound covering the semiconductor die.

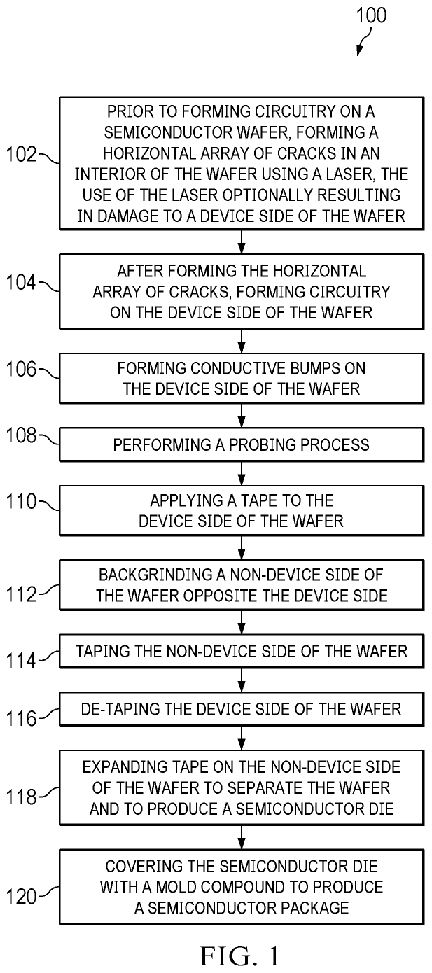

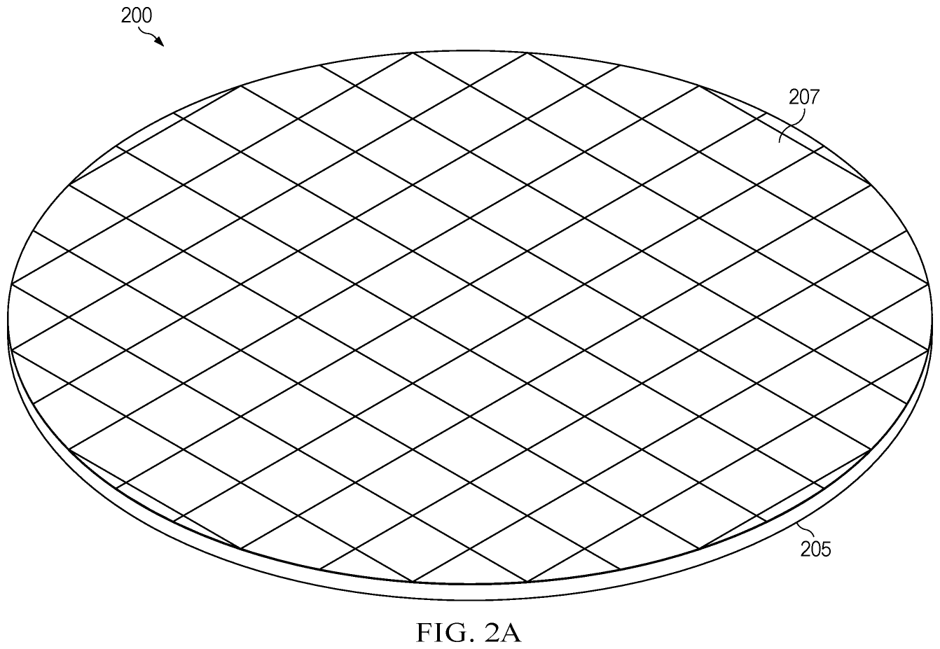

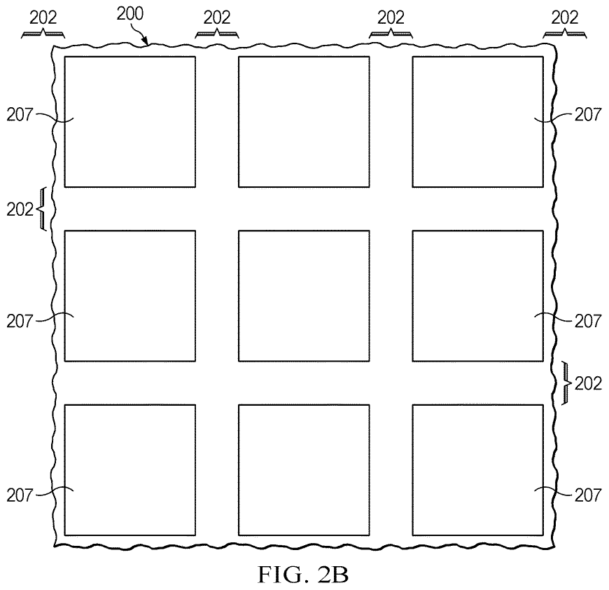

FIG. 1 is a flow diagram of a method 100 for manufacturing a semiconductor device, in accordance with various examples. FIGS. 2A-10C are a process flow for manufacturing a semiconductor device, in accordance with various examples. Accordingly, FIGS. 1 and 2A-10C are now described in parallel.

The method 100 begins with, prior to forming circuitry on a semiconductor wafer, forming a horizontal array of cracks (e.g., vertical cracks) in an interior of the wafer using a laser (102). The use of the laser may result in damage to a device side of the wafer (102). FIG. 2A shows a semiconductor wafer 200, possibly comprising silicon or another suitable semiconductor material such as gallium nitride. The semiconductor wafer 200 includes a device side 207 and a non-device side 205. Circuitry may be formed in and on the device side 207, as described below. The device side 207 may also include saw streets 202 that form a grid. The saw streets 202 circumscribe areas of the device side 207 in and/or on which circuitry may be formed. FIG. 2B is a top-down view of the device side 207.

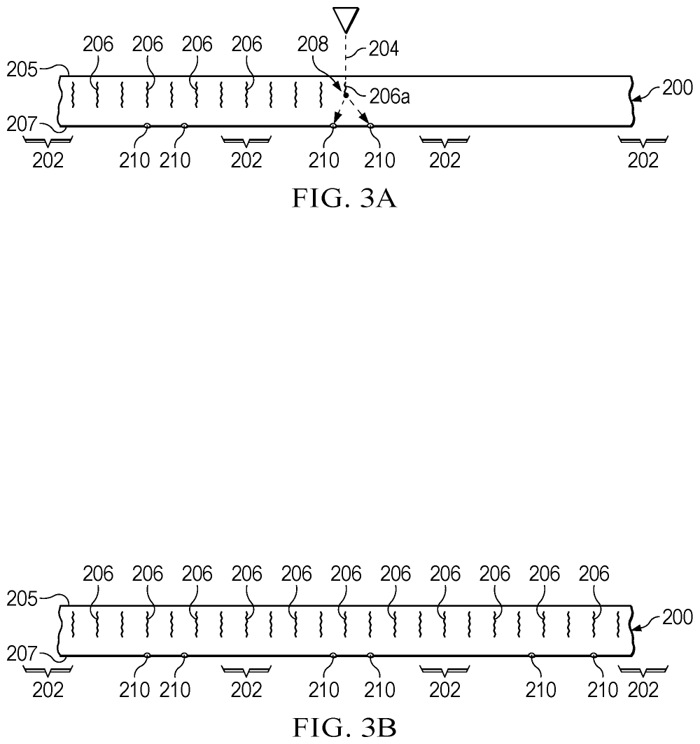

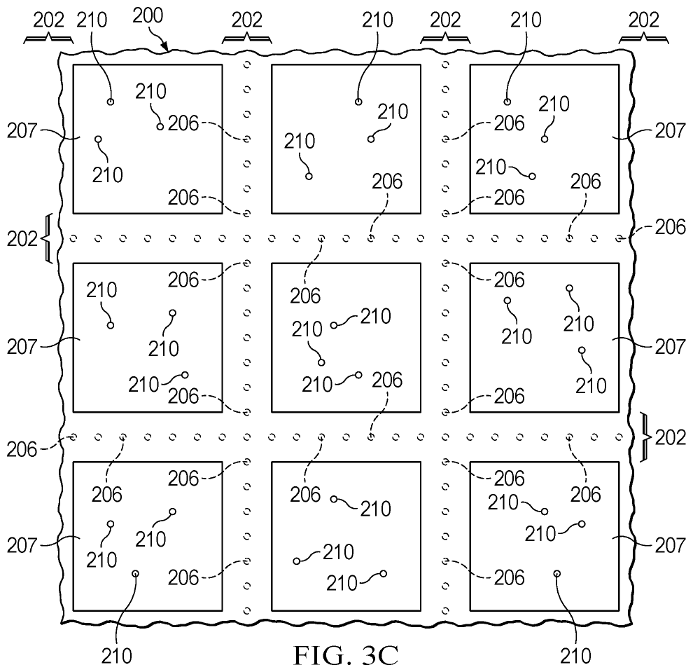

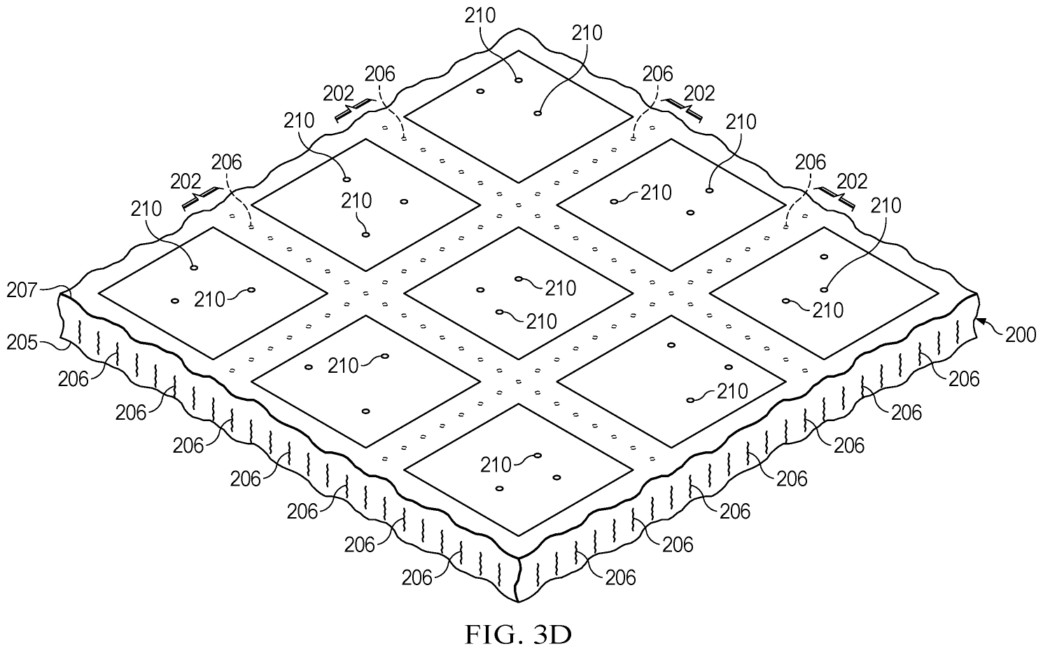

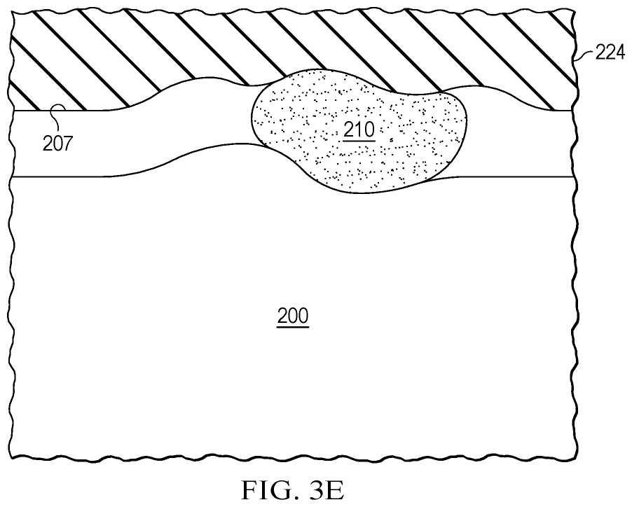

FIG. 3A is a cross-sectional view of the semiconductor wafer 200 as a horizontal array of vertical cracks are formed in the semiconductor wafer 200. In examples, a laser 204 is useful to form the vertical cracks in the semiconductor wafer 200.

The laser 204 applies laser pulses through the non-device side 205 to form vertical cracks 206. As shown in FIG. 3A, a horizontal array of the vertical cracks 206 is formed by the laser 204. The vertical cracks 206 extend in a vertical direction that is substantially perpendicular to the device side 207 and the non-device side 205. The laser 204 is applied through the non-device side 205 in locations that are in alignment with the saw streets 202 present on the device side 207.

During laser dicing, laser pulses are provided through a focusing lens to the semiconductor wafer 200. The laser pulse is focused on a level of the semiconductor wafer 200, such as the modify layer in the semiconductor wafer 200, which is determined based on the focusing lens, resulting in compressive stress within the modify layer and tensile stress above and below the modify layer. The exact position at which the laser is focused is called the target position. A series of laser pulses are provided by the laser 204 in a certain cutting direction and along a certain saw street of the semiconductor wafer 200 as described above to form the vertical cracks 206. There is a space between vertically adjacent target positions in the semiconductor wafer 200 to ensure the vertical cracks 206 caused by the corresponding successive beams connect to each other in the vertical direction.

Each vertical crack 206 has a top end and a bottom end. The laser beams are provided with a certain power and at a certain frequency to ensure the bottom ends of the vertical cracks 206 do not extend to the device side 207 to avoid damaging the circuits. The laser 204 has a power range of 0.2 Watts to 2.0 Watts, with a power lower than this range being disadvantageous because the resulting crack is too small to help singulate the wafer, and with a power above this range being disadvantageous because the resulting crack is too deep and will separate the wafer prematurely during the fab process, thereby preventing completion of the manufacturing process. In addition, the laser 204 may have a frequency range of 60 kHz to 100 kHz.

A distance between the bottom end of a vertical crack 206 and the device side 207 is at least 30 microns, with a distance smaller than 30 microns being disadvantageous because the wafer will break prematurely before the manufacturing process can be completed. The vertical length of each vertical crack 206 and the distance between the bottom end of the vertical crack 206 and the device side 207 must be such that the semiconductor wafer 200 does not break apart after laser dicing and during handling, transferring, and taping. However, each vertical crack 206 extends to and is exposed at the non-device side 205 when a desired thickness is reached after backgrinding. The power, the frequency and the distance (Z height) between the horizontal level and the device side 207 (i.e., distance between a vertical crack 206 and the device side 207) can vary based on the energy absorption rate of the material of the semiconductor wafer 200, for example, depending on the doping density of the semiconductor wafer 200.

In examples, the laser dicing can extend through the full thickness of the semiconductor wafer 200, and can include one or more passes. For example, a first laser pass forms vertical cracks 206 in a first area of the semiconductor wafer 200 closer to the device side 207, and a second laser pass forms vertical cracks 206 in a second area of the semiconductor wafer 200 closer to the non-device side 205. In examples, the laser dicing only includes one laser pass to form vertical cracks 206 in an area of the semiconductor wafer 200 closer to the device side 207, and the portion of the semiconductor wafer 200 between the vertical cracks 206 and the non-device side 205 can be removed during backgrinding.

Referring still to FIG. 3A, the laser dicing process may produce a vertical crack 206a when the laser 204 is focused on a target position in the semiconductor wafer 200. A second vertical crack (not expressly shown) may be formed just below the vertical crack 206a by focusing the laser 204 on a target position 208. However, as shown, the vertical crack 206a has inadvertently crept toward the device side 207 and extends to the target position 208. Thus, when the laser 204 is applied to the target position 208, the laser light falls into the vertical crack 206a, causing scattering (known as “splashing”) of the light. The laser splash results in the formation of damaged areas 210 (e.g., melting of the semiconductor wafer 200). The damaged areas 210 are near or at the device side 207, as shown. FIG. 3B shows the semiconductor wafer 200 after completion of step 102. FIG. 3C is a top-down view of the device side 207, with the vertical cracks 206 formed within the semiconductor wafer 200, but not extending to the device side 207. FIG. 3D is a perspective view of the semiconductor wafer 200 of FIG. 3B. FIG. 3E shows an illustration of the semiconductor wafer 200, the device side 207, a polyimide or other insulative layer 224 contacting the device side 207, and an example damaged area 210 at the device side 207.

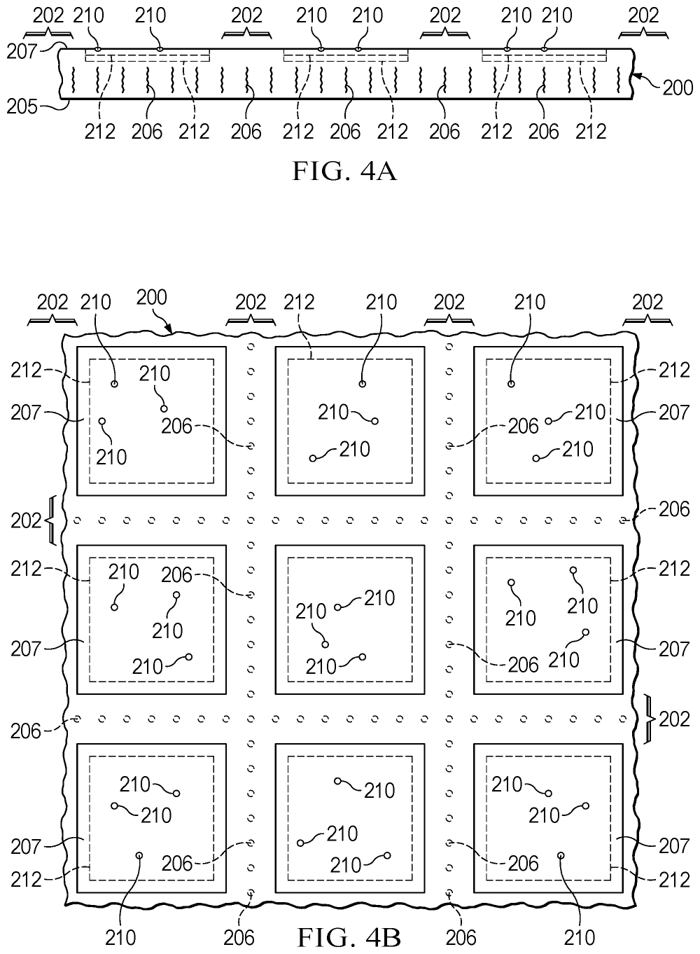

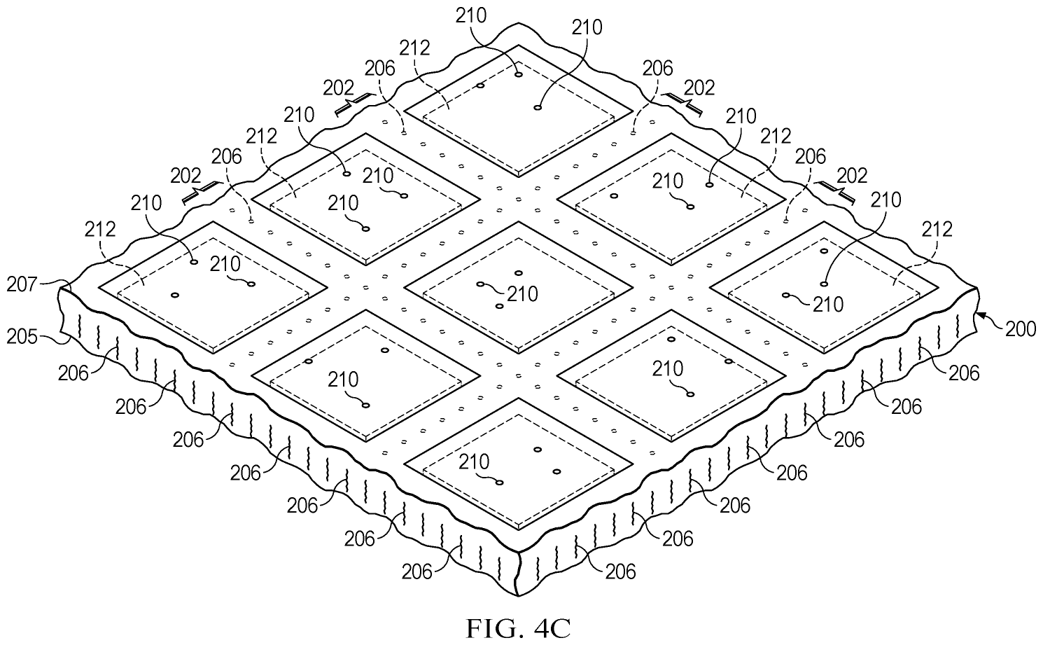

The method 100 includes, after forming the horizontal array of vertical cracks, forming circuitry on the device side of the wafer (104). Step 104 is a wafer fabrication step. FIG. 4A shows a cross-sectional view of the semiconductor wafer 200. Circuitry 212 is formed in and/or on the device side 207. The circuitry 212 can be configured to perform one or more functions. The circuitry 212 may include bond pads that function as input and output terminals for the circuitry 212. FIG. 4B is a top-down view of the device side 207. As shown, circuitry 212 is formed in the areas circumscribed by the grid of the saw streets 202. Further, vertical cracks 206 are formed within the semiconductor wafer 200 as described above, but the vertical cracks 206 are not visible at the device side 207. FIG. 4C is a perspective view of the semiconductor wafer 200 with circuitry 212 formed in the semiconductor wafer 200. The wafer fabrication step 104 may cause one or more of the vertical cracks 206 to extend in one or both vertical directions.

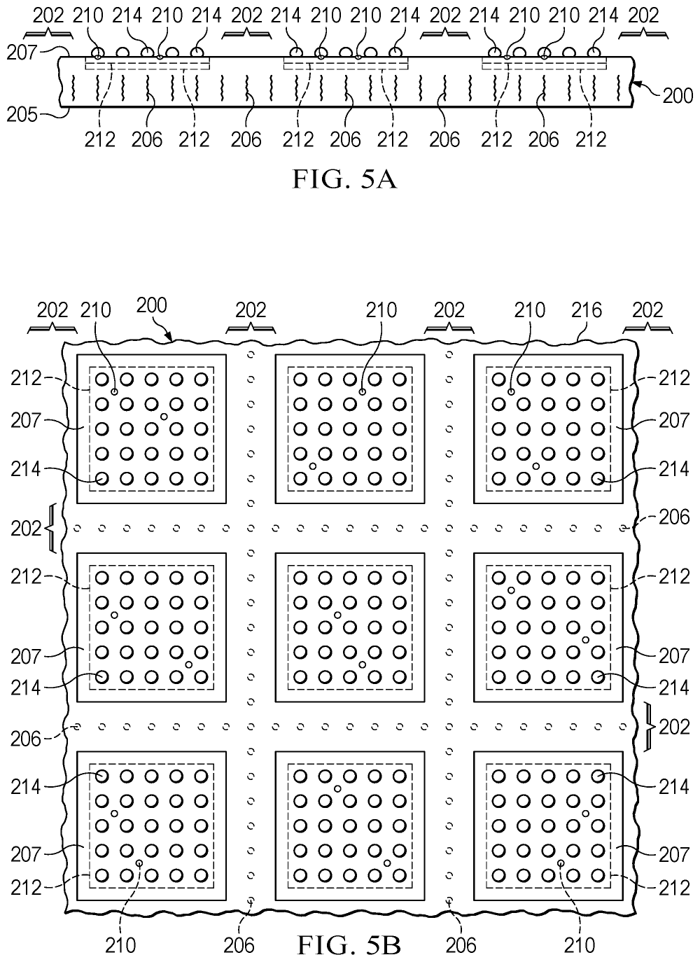

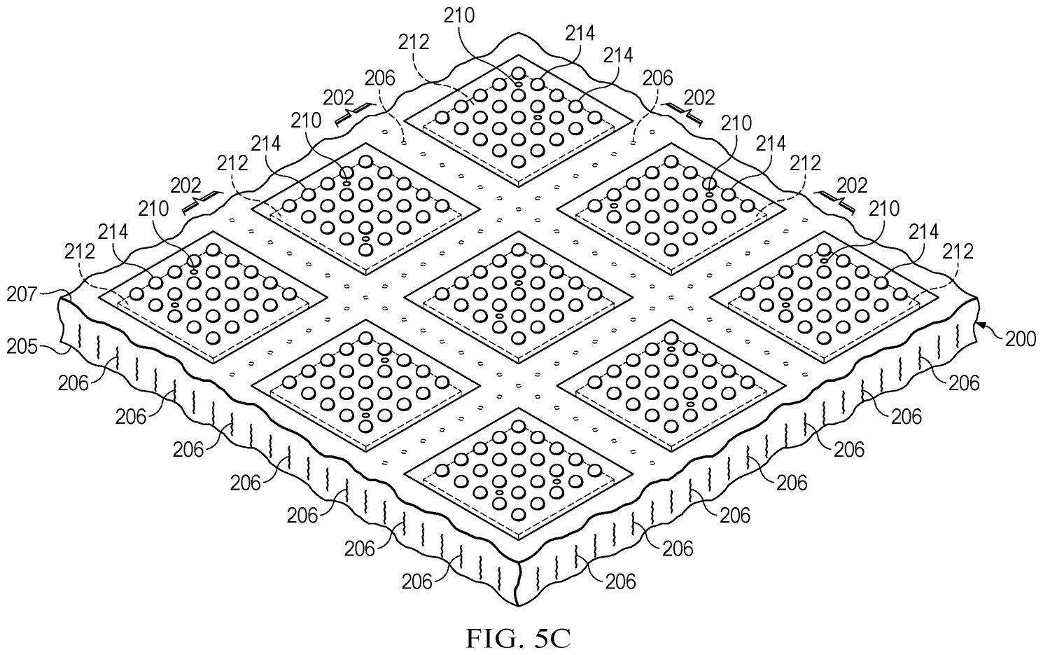

The method 100 includes forming conductive bumps on the device side of the wafer (106). The bumps may be metallic bumps, such as solder bumps. The bumps may be formed on bond pads connecting to the circuitry 212, for example. FIG. 5A shows example bumps 214 formed on or near the device side 207. FIG. 5B is a top-down view of the device side 207. FIG. 5C is a perspective view of the semiconductor wafer 200 including the bumps 214.

The method 100 includes performing a probing process (108). The probing process is performed to test the functionality of the circuitry 212. The probing process may use the bumps 214 to access the circuitry 212, in examples.

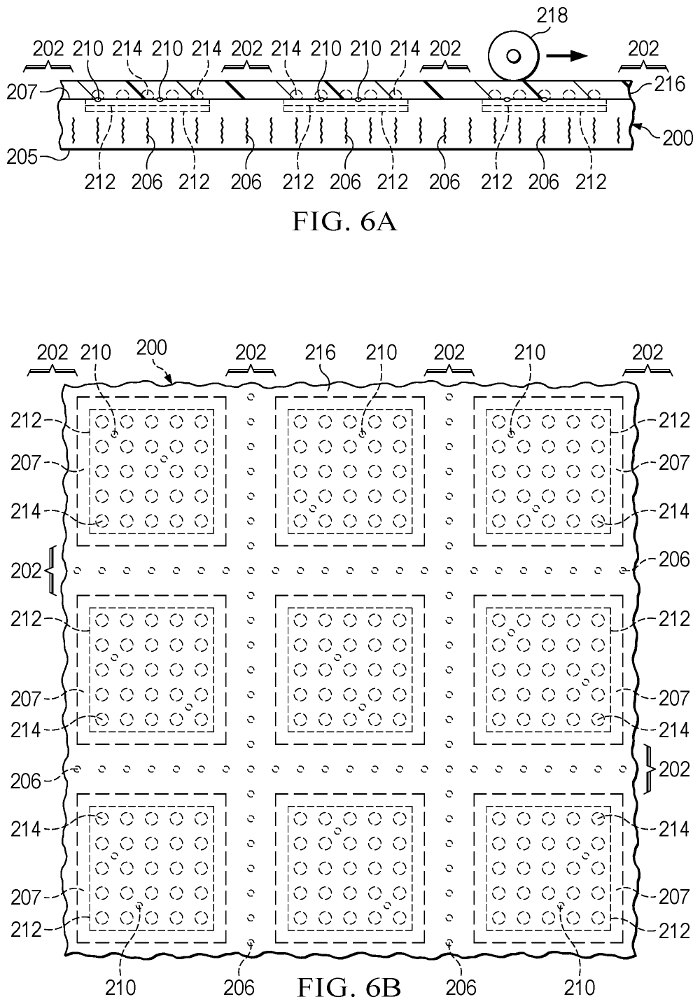

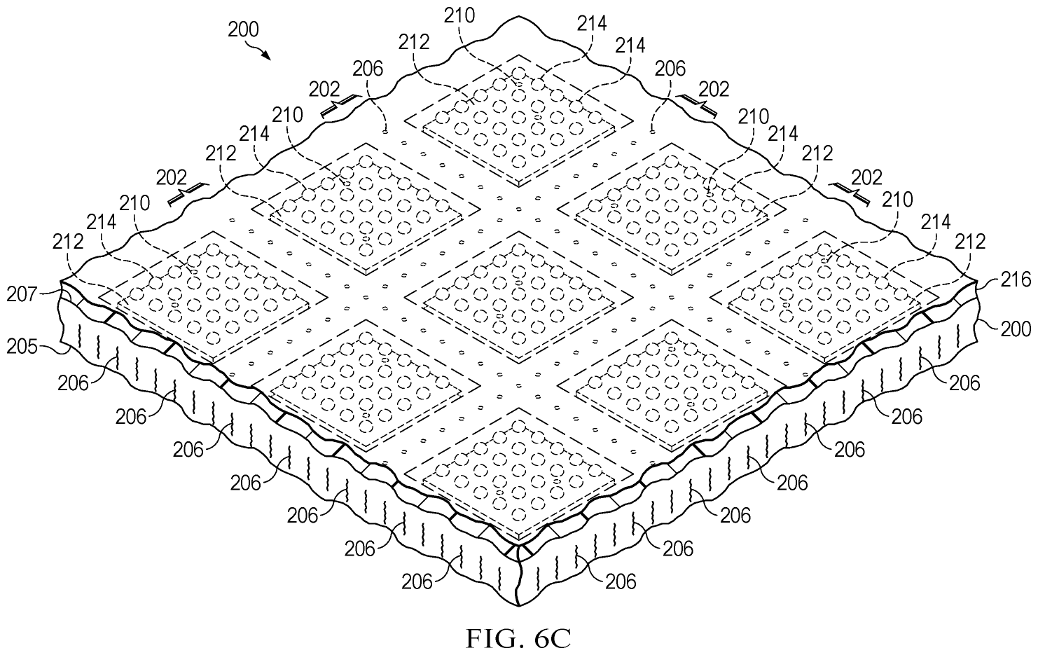

The method 100 includes applying a tape to the device side of the wafer (110). FIG. 6A is a cross-sectional view of the semiconductor wafer 200, depicting the application of a tape 216 using a roller 218. The tape 216 is applied to the device side 207. Examples of the tape 216 include E-3100 by LINTEC®. The pressure applied by the roller 218 may extend one or more of the vertical cracks 206 in one or more directions. FIG. 6B shows a top-down view of the device side 207, and FIG. 6C shows a perspective view of the semiconductor wafer 200 having the tape 216 applied to the device side 207.

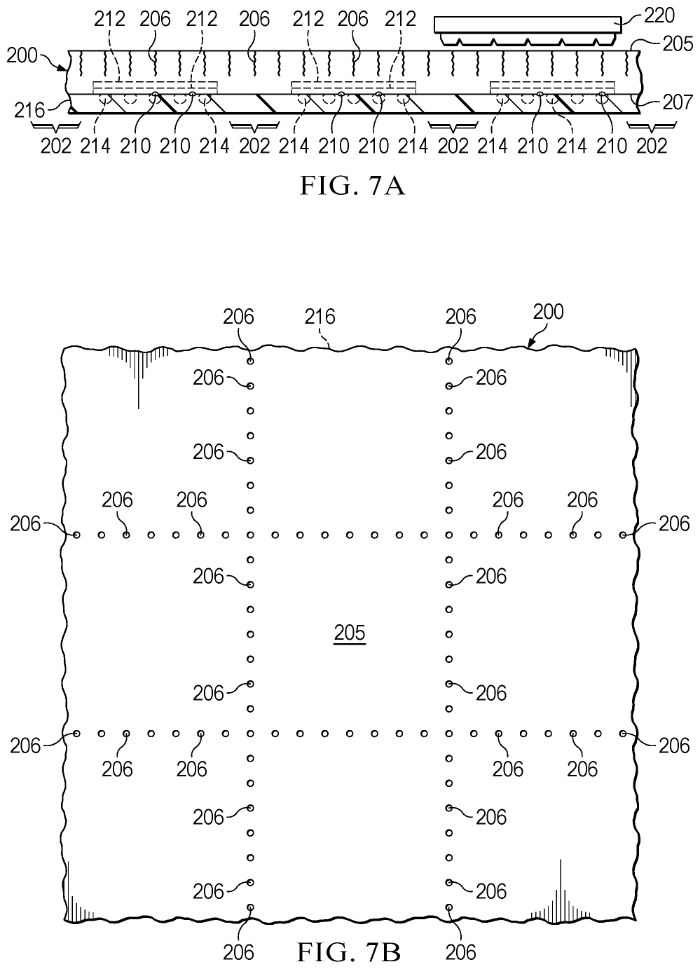

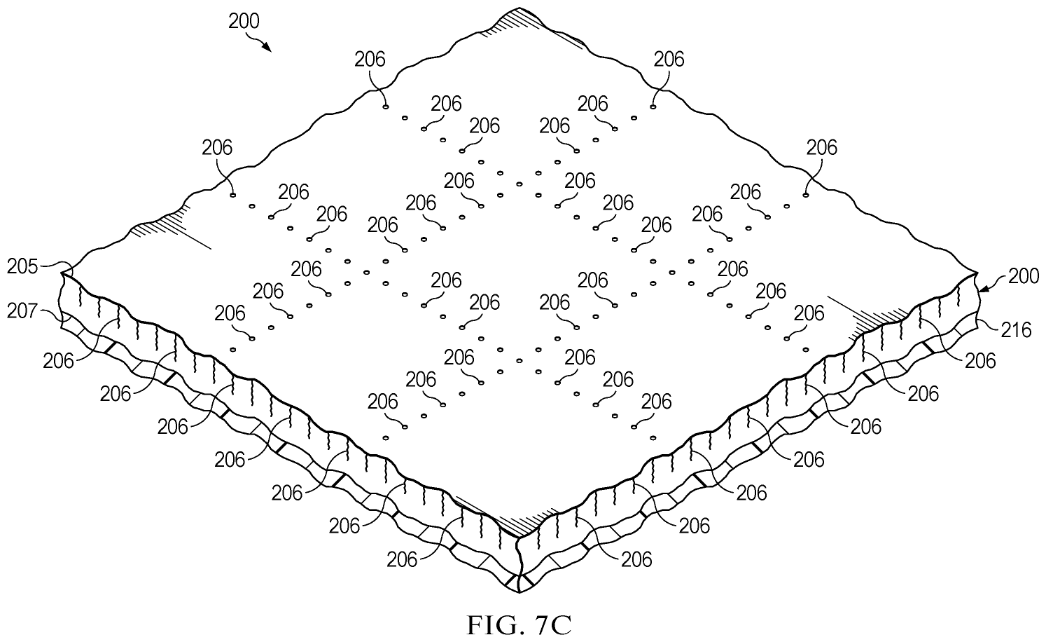

The method 100 includes backgrinding a non-device side of the semiconductor wafer opposite the device side (112). FIG. 7A shows a grinding wheel 220 being applied to the non-device side 205 to thin the semiconductor wafer 200. Grinding the semiconductor wafer 200 in this manner exposes any vertical cracks 206 that have not yet been exposed. Grinding can also cause further extension of one or more of the vertical cracks 206 in any vertical direction. The result is shown in FIG. 7B, which is a top-down view of the non-device side 205 having the vertical cracks 206 exposed. FIG. 7C is a perspective view of the thinned semiconductor wafer 200. The tape 216 keeps the semiconductor wafer 200 intact throughout the backgrinding process.

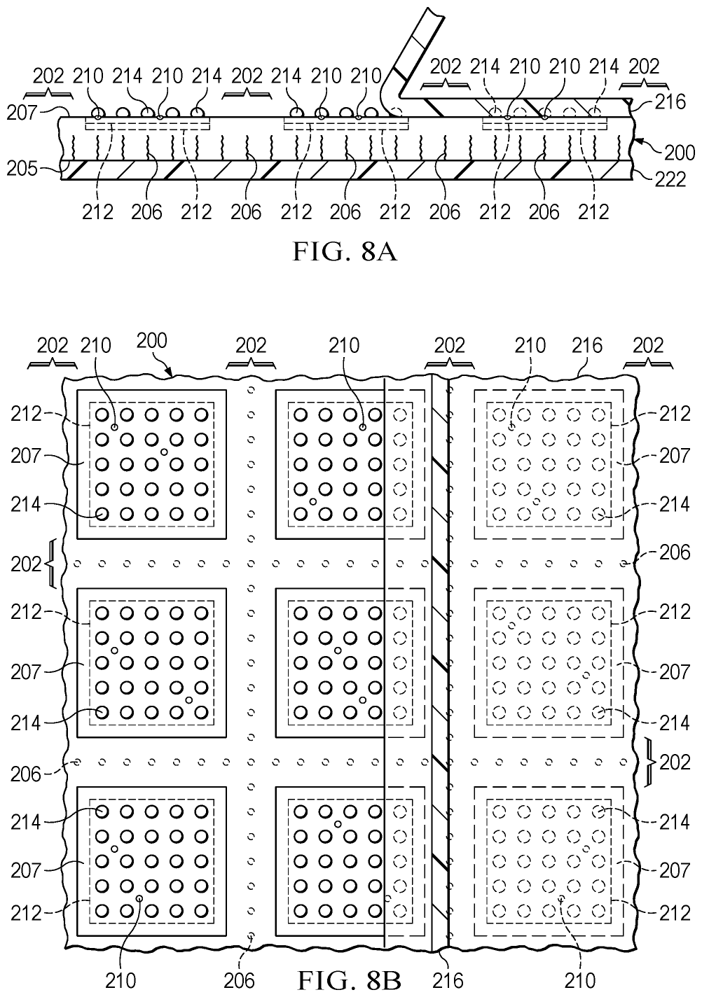

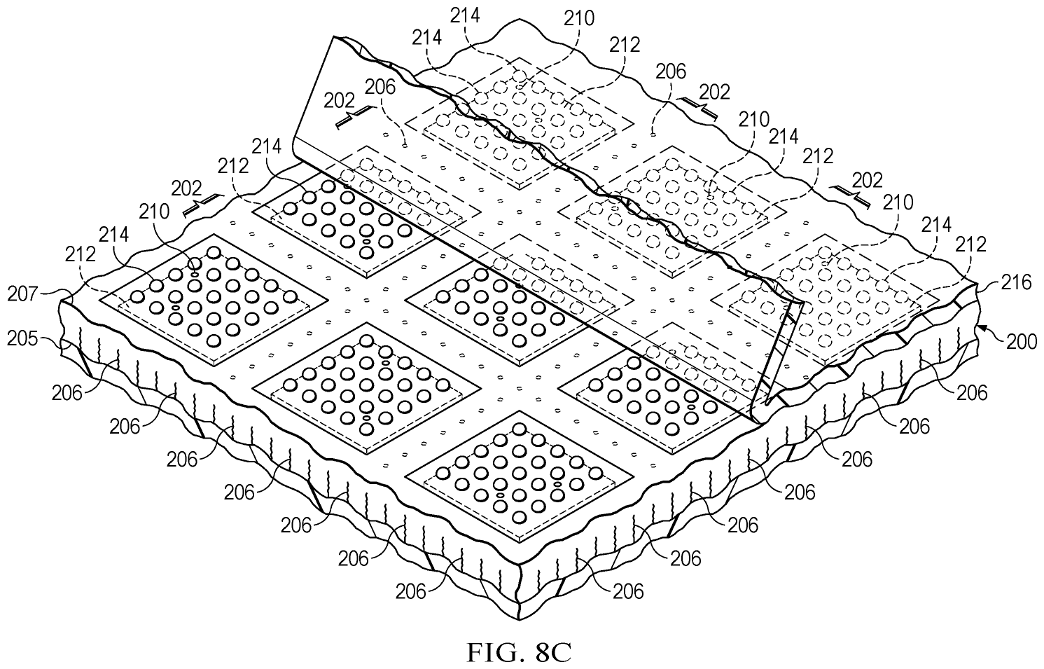

The method 100 includes taping the non-device side of the wafer (114) and de-taping the device side of the wafer (116). Taping the non-device side of the wafer may include mounting the semiconductor wafer 200 on an adhesive flex frame, for example. FIG. 8A shows a cross-sectional view of the tape 216 being removed from the device side 207, and further shows the non-device side 205 coupled to an adhesive flex frame 222. FIG. 8B is a top-down view of the structure of FIG. 8A. FIG. 8C is a perspective view of the structure of FIG. 8A.

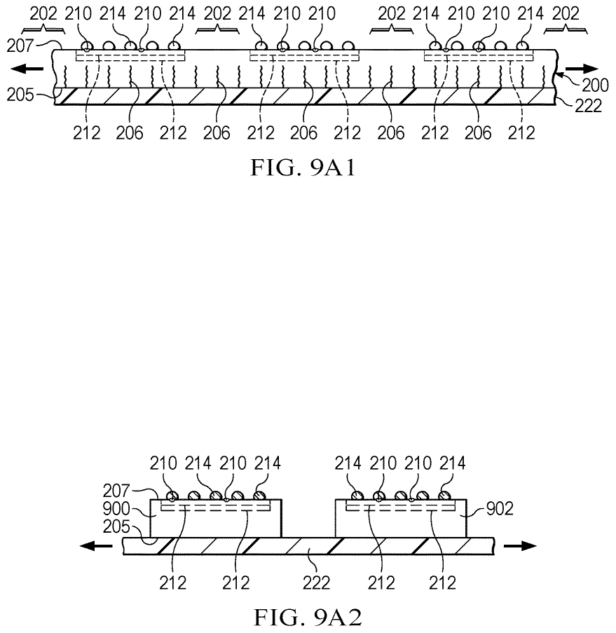

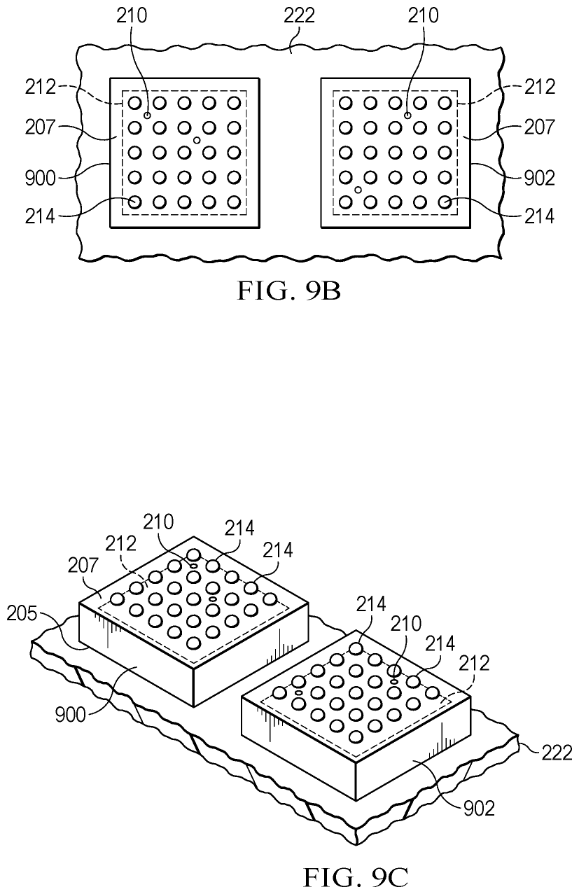

The method 100 includes expanding the tape on the non-device side of the wafer to separate the wafer and to produce a semiconductor die (118). FIG. 9A1 shows a cross-sectional view of the semiconductor wafer 200 coupled to the adhesive flex frame 222. As shown in FIG. 9A2, the adhesive flex frame 222 is stretched. Although the semiconductor wafer 200 is held together by the adhesive flex frame 222 and by the areas of the semiconductor wafer 200 that have not been vertically cracked, these areas of the semiconductor wafer 200 are very thin, and thus the stretching action of the adhesive flex frame 222 causes the semiconductor wafer 200 to fall apart, producing individual semiconductor dies 900 and 902. Each semiconductor die 900, 902 has its own circuitry 212, its own bumps 214, and so on. Even after separation of the semiconductor wafer 200 into semiconductor dies 900, 902, the semiconductor dies 900, 902 remain adhered to the adhesive flex frame 222. FIG. 9B is a top-down view of the structure of FIG. 9A2, and FIG. 9C is a perspective view of the structure of FIG. 9A2.

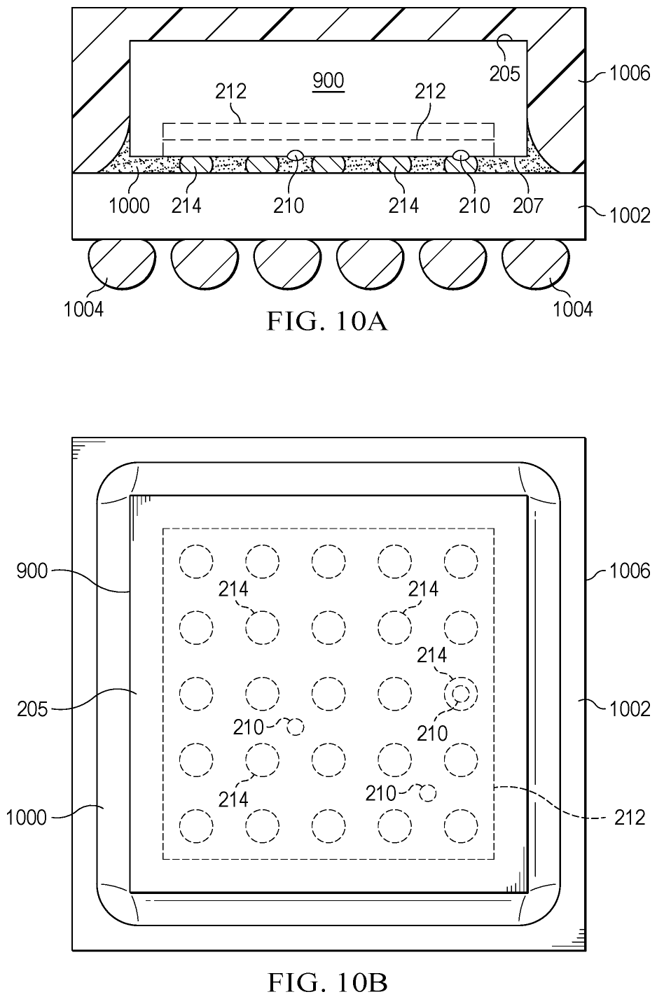

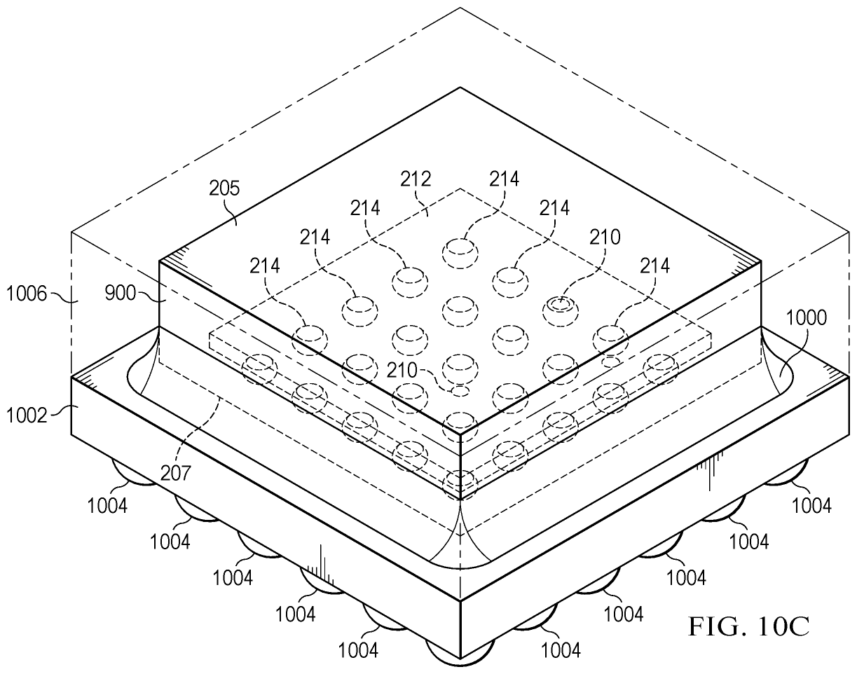

The method 100 includes covering the semiconductor die with a mold compound to produce a semiconductor package (120). FIG. 10A shows a semiconductor device (e.g., a semiconductor package) including the semiconductor die 900 coupled to a substrate 1002 having conductive traces, such as a redistribution layer (RDL). The semiconductor die 900 is coupled to the substrate 1002 by way of the bumps 214. An underfill 1000 is applied to the bumps 214 as shown. The conductive traces within the substrate 1002 are coupled to conductive terminals 1004 (e.g., solder bumps), which may be coupled to another electronic device, such as a printed circuit board (PCB). A mold compound 1006 covers the semiconductor die 900. As is shown, the semiconductor die 900 includes the damaged areas 210 at the device side 207, and the semiconductor die 900 includes the circuitry 212. Because the laser sawing process is performed before the circuitry 212 is formed, the damaged areas 210 are formed before the circuitry 212 is formed. Thus, the damaged areas 210 affect only the semiconductor material of the semiconductor wafer 200 and not the circuitry 212. The circuitry 212 is thus free of damage caused by laser splash, such as short-circuits caused by molten metal in the circuitry 212. This is a significant technical advantage of the techniques described herein.

Another technical advantage of the techniques described herein is that the saw streets 202 of the semiconductor wafer 200 (e.g., FIG. 2A) can be narrower than would otherwise be the case (e.g., less than 10 microns) because the circuitry 212 is not yet formed at the time of laser sawing, and thus the high heat zone generated by the laser beam that usually damages circuitry is no longer a consideration. Thus, the saw streets 202 can be narrowed to 10 microns or less. FIG. 10B is a top-down view of the structure of FIG. 10A. FIG. 10C is a perspective view of the structure of FIG. 10A.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A method for manufacturing a semiconductor die, comprising:
prior to forming circuitry on a semiconductor wafer, forming a horizontal array of cracks in an interior of the wafer using a laser;
after forming the horizontal array of cracks, forming circuitry on a device side of the wafer; and
forming conductive bumps on the device side of the wafer.

2. The method of claim 1, wherein forming the horizontal array of cracks includes forming a horizontal array of cracks that is vertically aligned with a saw street of the wafer.

3. The method of claim 2, wherein the saw street has a width no wider than 10 microns.

4. The method of claim 1, wherein forming the horizontal array of cracks using the laser comprises forming a first segment of a crack in a first location and subsequently a second segment of the crack in a second location, the first segment extending into the second location such that when the laser is applied to the second location, the laser scatters off of a contour of the second segment and extends to the device side of the wafer.

5. The method of claim 1, wherein forming the horizontal array of cracks comprises damaging the device side of the wafer by scattering of the laser, and wherein forming the circuitry comprises forming circuitry on a damaged area of the wafer.

6. The method of claim 5, wherein the damage on the device side includes a melting of the wafer.

7. The method of claim 1, wherein a minimum distance between a crack in the horizontal array of cracks and the device side of the wafer is 30 microns.

8. The method of claim 1, wherein a distance between a crack in the horizontal array of cracks and the device side of the wafer is a function of an energy absorption rate of a material of which the wafer is composed.

9. The method of claim 1, wherein a power and a frequency of the laser is a function of an energy absorption rate of a material of which the wafer is composed.

10. The method of claim 1, further comprising:
applying a tape to the device side of the wafer;
backgrinding a non-device side of the wafer opposite the device side; and
taping the non-device side of the wafer;
de-taping the device side of the wafer; and
expanding tape on the non-device side of the wafer to separate the wafer into individual, multiple semiconductor dies.

11. The method of claim 10, wherein backgrinding the non-device side of the wafer includes sufficiently grinding the non-device side to reveal the array of cracks in the wafer.

12. A method for manufacturing a semiconductor device, comprising:
receiving a semiconductor wafer having a horizontal array of cracks formed therein by a laser process, the laser process having damaged a device side of the wafer and circuitry having been thereafter formed on the device side such that the laser process did not damage the circuitry;
applying a tape to the device side of the wafer;
backgrinding a non-device side of the wafer opposite the device side;
taping the non-device side of the wafer;
de-taping the device side of the wafer;
expanding tape on the non-device side of the wafer to separate the wafer and to produce a semiconductor die;
coupling the semiconductor die to a conductive terminal; and
covering the semiconductor die with a mold compound to produce a semiconductor package, the conductive terminal exposed to an exterior of the semiconductor package.

13. The method of claim 12, wherein a saw street of the received wafer is 10 microns or less in width.

14. The method of claim 12, wherein the damage on the device side is formed by laser scatter off of a crack in the array of cracks.

15. The method of claim 12, wherein backgrinding the non-device side comprises backgrinding until the horizontal array of cracks is exposed.

16. The method of claim 12, wherein the damage on the device side includes melting of the wafer.

17. The method of claim 12, wherein a minimum distance between a crack in the horizontal array of cracks and the device side of the wafer is 30 microns.

18. A semiconductor device, comprising:
a semiconductor die having a device side in which circuitry is formed and a non-device side opposite the device side, the device side having sustained laser damage, the circuitry free of laser damage; and
a mold compound covering the semiconductor die.

19. The device of claim 18, wherein the circuitry is free of laser-induced short circuits.

20. The device of claim 18, wherein the laser damage comprises melting of a semiconductor material of which the semiconductor die is composed.
